(19) United States
(12) Patent Application Publication
(10) Pub. No.: US 2026/0076075 A1
(43) Pub. Date: Mar. 12, 2026

(54) DISPLAY PANEL, METHOD FOR MANUFACTURING THE SAME, AND DISPLAY DEVICE

(71) Applicant: HKC CORPORATION LIMITED, Shenzhen (CN)

(72) Inventors: Chenchen JIANG, Shenzhen (CN); Xiufeng ZHOU, Shenzhen (CN); Zhisheng XIE, Shenzhen (CN); Yangling TANG, Shenzhen (CN); Qin LIANG, Shenzhen (CN); Zhi YANG, Shenzhen (CN); Pei XU, Shenzhen (CN)

(21) Appl. No.: 19/304,663

(22) Filed: Aug. 20, 2025

(30) Foreign Application Priority Data
Aug. 30, 2024 (CN) 202411216129.6

(51) Int. Cl. H10K 59/80; H10K 59/12

(52) U.S. Cl. CPC H10K 59/873; H10K 59/1201; H10K 59/80524

(57) ABSTRACT

A display panel, a method for manufacturing the same, and a display device are disclosed. The display panel includes a substrate, a light-emitting element layer, a transparent barrier layer, a metal film layer, and an encapsulation layer. The light-emitting element layer is disposed on the substrate and is located within the display area. The transparent barrier layer is disposed on the light-emitting element layer and extends from the display area to the non-display area. The metal film layer is disposed in the non-display area and is located in the same layer as the transparent barrier layer. The encapsulation layer extends from the display area to the non-display area and is disposed on the transparent barrier layer and the metal film layer. The metal film layer is configured as a moisture-oxygen absorption layer to prevent moisture and oxygen from entering from below the encapsulation layer.

### CROSS-REFERENCE TO RELATED APPLICATIONS

This application claims the priority and benefit of Chinese patent application number 2024112161296, titled “Display Panel, Method for Manufacturing the Same, and Display Device” and filed Aug. 30, 2024 with China National Intellectual Property Administration, the entire contents of which are incorporated herein by reference.

### TECHNICAL FIELD

The present application relates to the field of display technologies, and more particularly relates to a display panel, a method for manufacturing the same, and a display device.

### BACKGROUND

The description provided in this section is intended for the mere purpose of providing background information related to the present application but does not necessarily constitute prior art.

Organic light-emitting diode (OLED) devices have become increasingly mature in mass production due to advantages such as surface light emission, cold light, energy saving, fast response, flexibility, ultra-thin profile, and low cost. Due to the poor stability of OLEDs and their extreme sensitivity to water and oxygen, encapsulation technology is particularly critical. The primary purpose of encapsulation is to prevent moisture and oxygen from entering the OLED. However, cracks are likely to form during the manufacturing process of the encapsulation layer. When cracks appear on the display screen or external moisture infiltrates, the aging rate of the OLED devices in the organic light-emitting layer accelerates. Therefore, rigorous encapsulation is necessary to achieve extended lifespan and improved stability.

However, the edge region of the display panel may be the weakest part of the encapsulation. During prolonged use, moisture and oxygen gradually infiltrate into the interior of the display panel from the encapsulation edges, resulting in encapsulation failure of the display panel.

### SUMMARY

It is therefore one purpose of the present application to provide a display panel, a method for manufacturing the same, and a display device. By providing a metal film layer as a moisture and oxygen absorbing layer, moisture and oxygen are prevented from entering from beneath the encapsulation layer, thereby improving the encapsulation performance of the display panel and extending the service life of the display panel.

The present application discloses a display panel. The display panel includes a display area and a non-display area. The display panel further includes a substrate, a light-emitting element layer, a transparent barrier layer, a metal film layer, and an encapsulation layer. The light-emitting element layer is disposed on the substrate and located in the display area. The transparent barrier layer is disposed on the light-emitting element layer and extends from the display area to the non-display area. The metal film layer is disposed in the non-display area and is located in the same layer as the transparent barrier layer. The encapsulation layer extends from the display area to the non-display area and is disposed on the transparent barrier layer and the metal film layer.

In some embodiments, the transparent barrier layer is formed using a cathode pattern material. The metal film layer is formed using a magnesium metal or silver metal material. After the transparent barrier layer is formed, the magnesium metal or silver metal material is deposited to form the metal film layer. In the display area, the cathode pattern material suppresses the adhesion of the magnesium metal or silver metal material, causing the metal film layer to be formed only in the non-display area.

In some embodiments, the encapsulation layer includes a first inorganic layer, an organic encapsulation layer, and a second inorganic layer. The first inorganic layer is disposed on the transparent barrier layer and the metal film layer. The organic encapsulation layer is disposed on the first inorganic layer. The second inorganic layer is disposed on the organic encapsulation layer. The display panel further includes an encapsulation barrier layer, which is disposed in the non-display area. The encapsulation barrier layer is used to block the organic encapsulation layer. The first inorganic layer and the second inorganic layer extend from the encapsulation barrier layer in a direction of getting farther away from the display area. On the encapsulation barrier layer, the first inorganic layer and the second inorganic layer are in direct contact with each other.

In some embodiments, the display panel further includes at least two blocking structures, which are disposed on the side of the encapsulation barrier layer facing towards the display area and positioned below the first inorganic layer. A gap is defined between the at least two blocking structures, and the metal film layer covers the at least two blocking structures and the gap.

In some embodiments, the metal film layer includes at least one annular notch. The at least one annular notch divides the metal film layer into a first metal ring portion and a second metal ring portion. The at least one annular notch is disposed surrounding the non-display area.

In some embodiments, the metal film layer includes at least one annular notch. The at least one annular notch divides the metal film layer into a first metal ring portion and a second metal ring portion. The at least one annular notch is disposed surrounding the non-display area.

In some embodiments, the metal film layer further includes an annular oxide portion, a first metal ring portion, and a second metal ring portion. The first metal ring portion is disposed surrounding the display area. The annular oxide portion is disposed surrounding the first metal ring portion. The second metal ring portion is disposed surrounding the annular oxide portion. The annular oxide portion of an oxidized metal material is formed by oxidizing the metal film layer.

The present application further discloses a method for manufacturing a display panel, the method including:
providing a substrate;
forming a light-emitting element layer on the substrate, where the light-emitting element layer is disposed in the display area;
forming a transparent barrier layer on the light-emitting element layer, with the transparent barrier layer extending from the display area to the non-display area;
forming a metal film layer in the non-display area, with the metal film layer located in the same layer as the transparent barrier layer; and
forming an encapsulation layer, with the encapsulation layer extending from the display area to the non-display area and covering the transparent barrier layer and the metal film layer.

In some embodiments, the transparent barrier layer is formed using a cathode pattern material, and the metal film layer is formed using a magnesium metal or silver metal material. The operation of forming the metal film layer in the non-display area, with the metal film layer located in the same layer as the transparent barrier layer includes:
depositing a magnesium metal or silver metal material over the entire surface; and
suppressing the adhesion of the magnesium metal or silver metal material within the display area by the cathode pattern material, so that the metal film layer is formed only in the non-display area.

The present application further discloses a display device, including a driving circuit and the display panel mentioned above, where the driving circuit is used to drive the display panel for display.

This application sets a metal film layer beneath the encapsulation layer in the non-display area. By utilizing the capability of absorbing water and oxygen of the metal film layer to a certain extent, when issues like edge encapsulation failure or aging of the display panel over long-term use lead to water and oxygen intrusion into the metal film layer, the metal film layer absorbs water and oxygen by sacrificing itself. That is, by oxidizing and corroding the metal film layer, it absorbs water and oxygen to prevent further intrusion of water and oxygen into the display area. Furthermore, this application prevents the formation of the metal film layer from affecting the light-emitting elements in the display area during the manufacturing process by setting the transparent barrier layer. In this way, without affecting the display panel, the resistance of the display panel to moisture and oxygen is improved. This enhances the encapsulation reliability of the display panel and extends the service life of the display panel.

### BRIEF DESCRIPTION OF DRAWINGS

The accompanying drawings are used to provide a further understanding of the embodiments according to the present application, and constitute a part of the specification. They are used to illustrate the embodiments according to the present application, and explain the principles of the present application in conjunction with the text description. Apparently, the drawings in the following description merely represent some embodiments of the present disclosure, and for those having ordinary skill in the art, other drawings may also be obtained based on these drawings without investing creative. In the drawings:

FIG. 1 is a schematic diagram of a display panel according to a first embodiment of the present application.

FIG. 2 is a schematic diagram of a second type of display panel according to the first embodiment of the present application.

FIG. 3 is a schematic diagram of a third type of display panel according to the first embodiment of the present application.

FIG. 4 is a schematic diagram of a first type of display panel according to a second embodiment of the present application.

FIG. 5 is a cross-sectional view taken along the cutting line AA′ shown in FIG. 4.

FIG. 6 is a top view schematic diagram of a metal film layer according to the present application.

FIG. 7 is a schematic diagram of a second type of display panel according to the second embodiment of the present application.

FIG. 8 is a flowchart of a method for manufacturing a display panel according to the present application.

FIG. 9 is a schematic diagram of a display device according to the present application.

In the drawings: 100, display panel; 101, display area; 102, non-display area; 110, substrate; 111, driving circuit layer; 120, light-emitting element layer; 121, light-emitting element; 122, anode; 123, organic light-emitting layer; 124, cathode; 130, transparent barrier layer; 140, metal film layer; 141, annular notch; 142, first metal ring portion; 143, second metal ring portion; 144, annular oxide portion; 145, hollow portion; 150, encapsulation layer; 151, first inorganic layer; 152, organic encapsulation layer; 153, second inorganic layer; 160, encapsulation barrier layer; 170, blocking structure; 171, gap; 200, display device; 210, driving circuit.

### DETAILED DESCRIPTION OF EMBODIMENTS

It should be understood that the terms used herein, the specific structures and functional details disclosed therein are merely representative for describing some specific embodiments, but the present application can be implemented in many alternative forms and should not be construed as being limited to only these embodiments described herein.

As used herein, terms “first”, “second”, or the like are merely used for illustrative purposes, and shall not be construed as indicating relative importance or implicitly indicating the number of technical features specified. Thus, unless otherwise specified, the features defined by “first” and “second” may explicitly or implicitly include one or more of such features. Terms “multiple”, “a plurality of”, and the like mean two or more. In addition, terms “up”, “down”, “left”, “right”, “vertical”, and “horizontal”, or the like are used to indicate orientational or relative positional relationships based on those illustrated in the drawings. They are merely intended for simplifying the description of the present disclosure, rather than indicating or implying that the device or element referred to must have a particular orientation or be constructed and operate in a particular orientation. Therefore, these terms are not to be construed as restricting the present disclosure. For those of ordinary skill in the art, the specific meanings of the above terms as used in the present application can be understood depending on specific contexts.

The present application will be described in detail below with reference to the accompanying drawings and some optional embodiments.

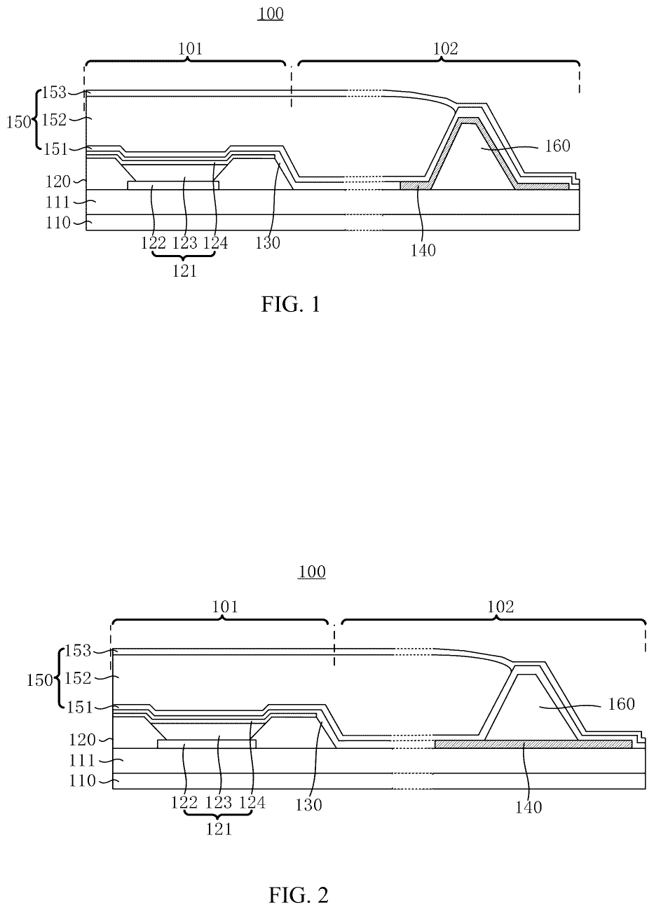

FIG. 1 is a schematic diagram of a display panel according to a first embodiment of the present application. Referring to FIG. 1, the present application discloses a display panel 100. The display panel 100 includes a display area 101 and a non-display area 102. The display panel 100 further includes a substrate 110, a light-emitting element layer 120, a transparent barrier layer 130, a metal film layer 140, and an encapsulation layer 150. The light-emitting element layer 120 is disposed above the substrate 110 and is disposed within the display area 101. The transparent barrier layer 130 is disposed on the light-emitting element layer 120 and extends from the display area 101 to the non-display area 102. The metal film layer 140 is disposed in the non-display area 102 and is located in the same layer as the transparent barrier layer 130. The encapsulation layer 150 extends from the display area 101 to the non-display area 102 and is disposed on the transparent barrier layer 130 and the metal film layer 140.

In the present application, a metal film layer 140 is disposed below the encapsulation layer 150 in the non-display area 102, and the metal film layer 140 has a certain capacity to absorb moisture and oxygen. When encapsulation failure occurs at the edge of the display panel 100 or aging problems arise after prolonged use resulting in moisture and oxygen intrusion into the position of the metal film layer 140, the moisture and oxygen can be absorbed by sacrificing the metal film layer 140. That is, the moisture and oxygen are absorbed through the oxidation and corrosion of the metal film layer 140, thereby preventing further intrusion of the moisture and oxygen into the display area 101. Furthermore, in the present application, by providing the transparent barrier layer 130, it is possible to prevent the light-emitting elements 121 in the display area 101 from being affected during the formation of the metal film layer 140 due to process-related reasons, thereby improving the resistance to moisture and oxygen of the display panel 100 without affecting the display panel 100, enhancing the encapsulation reliability of the display panel 100 and extending its service life.

It can be understood that the primary purpose of the metal film layer 140 provided in the present application is to extend the service life of the display panel 100. That is, the encapsulation of the display panel 100 is intact before leaving the factory, but after prolonged use, a small amount of moisture and oxygen intrusion occurs at the edges of the display panel 100. In actual aging tests, the relationship between the amount of moisture and oxygen and time after prolonged use can be determined by simulation, thereby setting an appropriate amount of metal film layer 140 for moisture and oxygen absorption, thus extending the service life of the display panel 100.

In one embodiment, the transparent barrier layer 130 may be formed from an insulating material, where the insulating material includes an organic insulating material or an inorganic insulating material. By forming the transparent barrier layer 130 on the light-emitting element layer 120 within the display area 101, the transparent barrier layer 130 prevents direct contact between the metal film layer 140 and the light-emitting element 121 during the subsequent formation of the metal film layer 140. Since the metal film layer 140 may need to be deposited over the entire surface and then patterned through an etching process, the transparent barrier layer 130 in this embodiment also prevents damage to the light-emitting element layer 120 during the etching of the metal film layer 140.

The light-emitting element layer 120 may include a plurality of light-emitting elements 121 arranged in an array. Each light-emitting element 121 may include an anode 122, an organic light-emitting layer 123, and a cathode 124. The cathode 124 is disposed at the top. The anode 122 is disposed at the bottom. The organic light-emitting layer 123 is disposed between the anode 122 and the cathode 124. The electric field generated by the anode 122 and cathode 124 drives the organic light-emitting layer 123 to emit light. Adjacent light-emitting elements 121 are separated by a pixel defining layer. The organic light-emitting layer 123 has a relatively high sensitivity to moisture and oxygen. After completing the manufacturing processes for multiple light-emitting elements 121, an encapsulation layer 150 needs to be directly formed to prevent subsequent manufacturing processes from affecting the light-emitting elements 121. In this embodiment, although a transparent barrier layer 130 is formed on the light-emitting element layer 120, there still exists a possibility that the effectiveness of the light-emitting elements 121 may be affected during the subsequent etching of the metal film layer 140.

In another embodiment, the transparent barrier layer 130 is formed using a cathode pattern material. The cathode pattern material can be deposited onto the light-emitting elements 121 by vacuum deposition. It is a non-uniformly substituted fluorinated cyclotriphosphazene compound with a lotus effect that inhibits the adhesion of active metals such as magnesium and silver. In this embodiment, the metal film layer 140 is formed using a magnesium metal or silver metal. Through the inhibiting effect of the transparent barrier layer 130, the deposition of magnesium metal or silver metal on the transparent barrier layer 130 can be prevented. In particular, after forming the transparent barrier layer 130, the magnesium metal or silver metal material is deposited over the entire surface. In the display area 101, the cathode pattern material inhibits the adhesion of the magnesium metal or silver metal material, so that the metal film layer 140 is formed only in the non-display area 102.

As used herein, the term “lotus effect” refers to a surface property characterized by extremely low adhesion to foreign substances, inspired by the natural self-cleaning behavior observed in lotus leaves. This effect arises from a combination of micro-and nano-scale surface roughness and low surface energy, resulting in superhydrophobic and anti-adhesive characteristics. In the context of the present specification, a non-uniformly substituted fluorinated cyclotriphosphazene compound exhibiting the lotus effect forms part of a transparent barrier layer that inhibits the adhesion and deposition of active metals such as magnesium and silver. By repelling these metals, the lotus-effect surface ensures that metal film formation is limited to specific non-display regions, thereby preventing unwanted metal accumulation in the display area. This selective non-wettability enhances the performance and reliability of the device by maintaining the optical and electrical integrity of the active display region.

The advantage of this embodiment lies in that the metal film layer 140 can be patterned by controlling the region of the transparent barrier layer 130, and there is no need to remove excess metal film layer 140 through etching in subsequent processes. In contrast, the light-emitting elements 121 within the display area 101 can be protected from the impact of subsequent processes. With the function of the transparent barrier layer 130, the metal film layer 140 can be deposited over the entire surface of the display panel 100 before the encapsulation layer 150 is formed. Because the metal film layer 140 cannot adhere to the transparent barrier layer 130 within the display area 101, the metal film layer 140 is eventually formed only in the regions of the non-display area 102 that are not covered by the transparent barrier layer 130. Furthermore, the subsequent transparent barrier layer 130 does not affect the normal formation of the encapsulation layer 150.

In particular, in this embodiment, the metal film layer 140 may be arranged to surround the display area 101 and appears annular in an orthogonal projection onto the substrate 110. This is mainly based on the consideration that after the display panel 100 is properly encapsulated and shipped, the specific location of moisture and oxygen intrusion cannot be determined after prolonged use. Relatively speaking, aside from the higher intrusion risk at the corners of the display panel 100, each side of the display panel 100 has the same risk of intrusion. Therefore, the annularly arranged metal film layer 140 can minimize the risk of moisture intrusion at any specific location, thereby preventing display defects and maintaining the overall display effect.

Referring again to FIG. 1, the encapsulation layer 150 includes a first inorganic layer 151, an organic encapsulation layer 152, and a second inorganic layer 153. The first inorganic layer 151 is disposed on the transparent barrier layer 130 and the metal film layer 140. The organic encapsulation layer 152 is disposed on the first inorganic layer 151. The second inorganic layer 153 is disposed on the organic encapsulation layer 152.

In this embodiment, the encapsulation layer 150 is exemplified as a three-layer stack formed by an inorganic encapsulation material and an organic encapsulation material, but this does not imply that the encapsulation layer 150 of the present application is limited to a three-layer structure. Relatively speaking, the number of layers in the encapsulation layer 150 is not limited in the present application.

At the edge region of the display panel 100, the organic encapsulation layer 152 no longer extends, and the first inorganic layer 151 is in direct contact with the second inorganic layer 153; both the first inorganic layer 151 and the second inorganic layer 153 continue to extend to the edge of the display panel 100.

In this embodiment, the metal film layer 140 extends from the region of the non-display area 102 where the organic encapsulation layer 152 is present to the region where the organic encapsulation layer 152 is not disposed. In the orthogonal projection onto the substrate 110, the metal film layer 140 partially overlaps the organic encapsulation layer 152. The term “partially overlaps” here means that a portion of the orthogonal projection of the organic encapsulation layer 152 coincides with that of the metal film layer 140, while another portion does not. Conversely, a portion of the orthogonal projection of the metal film layer 140 overlaps that of the organic encapsulation layer 152, while another portion does not.

In one embodiment, the side of the metal film layer 140 facing away from the display area 101 is covered by the first inorganic layer 151. That is, in the direction facing away from the display area 101, the lengths of the first inorganic layer 151 and the second inorganic layer 153 extend beyond the metal film layer 140.

However, the organic encapsulation layer 152 in the encapsulation layer 150 is formed using inkjet printing. Based on inkjet printing, the organic encapsulation layer 152 needs to be leveled, and it is necessary to prevent ink overflow during the inkjet printing process of the organic encapsulation layer 152. In this regard, the display panel 100 further includes an encapsulation barrier layer 160, which is disposed in the non-display area 102. The encapsulation barrier layer 160 is used to block the organic encapsulation layer 152. The first inorganic layer 151 and the second inorganic layer 153 extend from the encapsulation barrier layer 160 in the direction of getting farther away from the display area 101. Furthermore, the first inorganic layer 151 and the second inorganic layer 153 are in direct contact with each other at the area of the encapsulation barrier layer 160.

The metal film layer 140 mentioned above can be disposed between the encapsulation barrier layer 160 and the first inorganic layer 151. The metal film layer 140 serves primarily to address the phenomenon of moisture and oxygen invasion at the film layer interface beneath the first inorganic layer 151.

FIG. 2 is a schematic diagram of a second type of display panel according to the first embodiment of the present application. Referring to FIG. 2, the display panel 100 in this embodiment is basically the same as the previous embodiment. In this embodiment, the metal film layer 140 can also extend from beneath the bottom of the organic encapsulation layer 152 towards under the bottom of the encapsulation barrier layer 160. In the orthogonal projection onto the substrate 110, the metal film layer 140 coincides with or partially overlaps the encapsulation barrier layer 160. In this embodiment, the side of the metal film layer 140 facing away from the display area 101 may be set the same as that in the previous embodiment, and so will not be repeated herein.

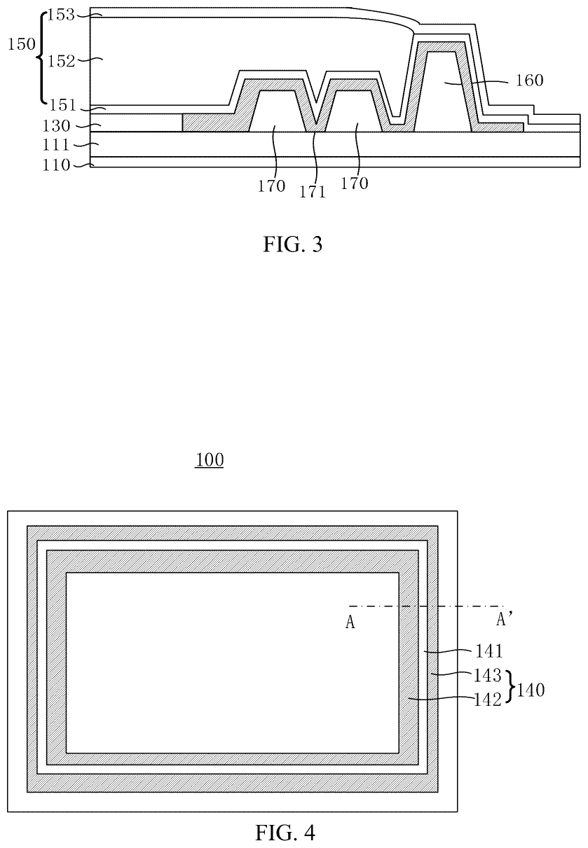

FIG. 3 is a schematic diagram of a third type of display panel according to the first embodiment of the present application. Referring to FIG. 3, furthermore, the display panel 100 (as illustrated in FIGS. 1 and 2) further includes at least two blocking structures 170, which are disposed on the side of the encapsulation barrier layer 160 facing towards the display area 101 and located beneath the first inorganic layer 151. A gap 171 is provided between the at least two blocking structures 170. The metal film layer 140 is configured to cover both of the at least two blocking structures 170 and the gap 171.

A driving circuit layer 111 may be disposed on the substrate 110, which is used to drive the plurality of light-emitting elements 121 in the light-emitting element layer 120 to emit light. The driving circuit layer 111 is disposed beneath the light-emitting element layer 120. In the non-display area 102, the driving circuit layer 111 includes extended circuits and other structures. The blocking structures 170 in this embodiment are also disposed on the driving circuit layer 111, beneath the encapsulation layer 150.

In this embodiment, the blocking structures 170 protrude from the driving circuit layer 111, so that when the metal film layer 140 is formed, the layer beneath the metal film layer 140 has an uneven surface structure, causing the metal film layer 140 to change heights in congruence with the layer of the blocking structures 170, thus achieving a longer path for the metal film layer 140. Furthermore, and more importantly, at the groove position between the blocking structures 170, during the deposition of the metal film layer 140, more metal film layer 140 will accumulate, making the thickness of the metal film layer 140 greater, thereby enhancing the capability of the metal film layer 140 of absorbing moisture and oxygen.

The number of blocking structures 170 can be designed depending on the actual situation. The manufacturing process of forming the blocking structures 170 can be synchronized with that of forming the encapsulation barrier layer 160, but the height of the blocking structures 170 can be lower than that of the encapsulation barrier layer 160. The blocking structure 170 in this embodiment can be combined with the different embodiments in which the metal film layer 140 is disposed above or below the encapsulation barrier layer 160.

In one embodiment, grooves may alternatively be defined in the blocking structure 170 to form an uneven layer structure, so that during the formation of the metal film layer 140, an uneven metal film layer 140 can also be formed.

It can be understood that the setup in this embodiment is also applicable to the display panel 100 in the previous embodiments. By setting protruding blocking structures 170 or grooves, the thickness of the metal film layer 140 can be increased, and the path for water and oxygen invasion is also lengthened.

### Second Embodiment

Considering that corrosion of metal after absorbing water and oxygen tends to spread, when water and oxygen invade the encapsulation layer 150 of the display panel 100, corrosion of the metal film layer 140 will spread. Based on this, further improvements are made in this embodiment.

FIG. 4 is a schematic diagram of a first type of display panel according to a second embodiment of the present application. FIG. 5 is a cross-sectional schematic view taken along the cutting line AA′ shown in FIG. 4. Referring to FIGS. 4 to 5, and also with reference to FIGS. 1 to 3, the present application further discloses a display panel 100. The display panel 100 includes a substrate 110, a light-emitting element layer 120, a transparent barrier layer 130, a metal film layer 140, and an encapsulation layer 150. The metal film layer 140 includes at least one annular notch 141, and the annular notch 141 divides the metal film layer 140 into a first metal ring portion 142 and a second metal ring portion 143. The annular notch 141 is arranged to surround the non-display area 102.

In this embodiment, the metal film layer 140 is divided into at least the first metal ring portion 142 and the second metal ring portion 143 by means of the annular notch 141. The first metal ring portion 142 is arranged in the inner circle, and the second metal ring portion 143 surrounds the first metal ring portion 142. After the second metal ring portion 143 in the outer circle is corroded by moisture and oxygen, the metal corrosion may gradually extend along the metal. At the notch position, the metal corrosion is difficult to extend. Therefore, it can prevent the further extension of the moisture and oxygen corrosion. When the second metal ring portion 143 in the outer circle is not completely corroded, it can protect the first metal ring portion 142 from corrosion. For example, when a small amount of moisture and oxygen extends from a certain point, if there is no notch, the metal corrosion will spread outward from the initial corrosion position as the center. Relatively speaking, when the extension speed along the vertical direction towards the display area 101 and the extension speed towards the lateral direction along the edge are the same, it will result in the inner side of the metal film layer 140 being corroded and spreading, while the metal film layer 140 at other positions on the outer side may still remain intact. For example, after setting the annular notch 141 in this embodiment, when a small amount of moisture and oxygen extends from a certain point, the metal corrosion spread in the second metal ring portion 143 will only extend laterally and will not extend vertically. That is, it will not spread to the first metal ring portion 142. When the amount of moisture and oxygen intrusion from the outside reaches the limit that the second metal ring portion 143 is able to absorb, the moisture and oxygen will then be absorbed by the first metal ring portion 142. The vertical spreading direction refers to the direction towards the display area 101, while the lateral spreading direction is perpendicular to the vertical spreading direction. More In particular, the vertical spreading direction refers to the direction from each of the four edges of the display panel towards the display area 101, while the lateral spreading refers to the direction along each edge of the display panel. In one embodiment, the annular notch 141 can be formed by etching. That is, after forming the metal film layer 140 in the non-display area 102, the portion of the metal film layer 140 at the position of the annular notch 141 is removed through an etching process.

In another embodiment, by arranging an extension of the transparent barrier layer 130 at the position of the annular notch 141, the extension of the transparent barrier layer 130 is synchronously formed at the position of the annular notch 141 during the process of forming the transparent barrier layer 130. This ensures that during the formation of the metal film layer 140, no metal film layer 140 is formed at the position of the annular notch 141.

Furthermore, the number of annular notches 141 and the width of the first metal ring portion 142 or the second metal ring portion 143 can be selected depending on the actual situation. When more annular notches 141 are set, the multi-stage annular metal film layers 140 can be formed, achieving multi-stage prevention of corrosion propagation.

In this embodiment, when multiple blocking structures 170 are disposed in the display panel 100, the annular notch 141 can be correspondingly disposed between the multiple blocking structures 170, thus forming the first metal ring portion 142 or second metal ring portion 143 between two blocking structures 170. On one hand, the metal film layer 140 formed between two blocking structures 170 has a greater thickness than the metal film layer 140 formed on the blocking structure 170, providing better absorption. On the other hand, adding a film layer on the blocking structure 170 reduces the leveling area of the organic encapsulation layer 152, leading to issues with the leveling of the organic encapsulation layer 152.

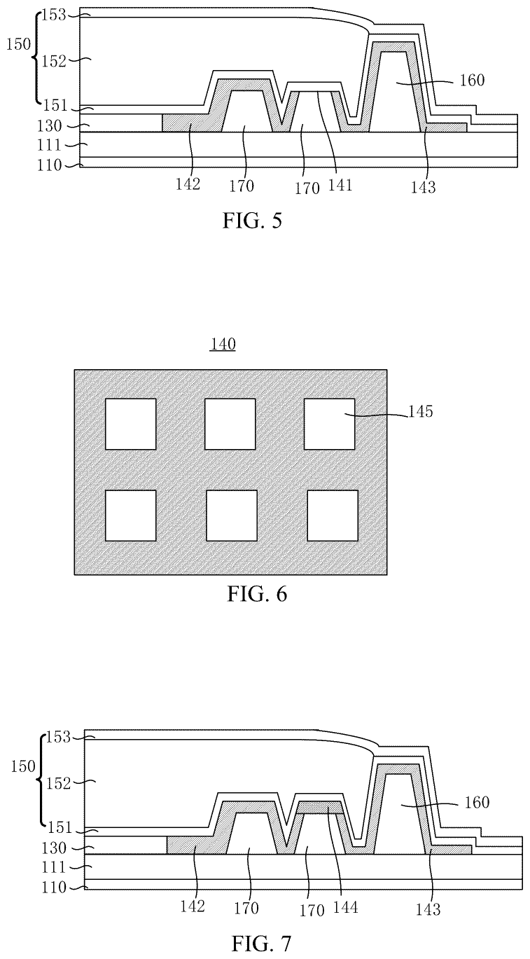

FIG. 6 is a top view schematic diagram of a metal film layer according to the present application. Referring to FIG. 6, the metal film layer 140 includes a plurality of hollow portions 145, which are arranged in an array. The metal film layer 140 is of a mesh structure. In this embodiment, by setting multiple hollow portions 145 within the metal film layer 140, the metal film layer 140 is configured as multiple strip-shaped metal film layers that are arranged in a crisscross pattern. By setting the hollow portions 145, the speed of metal corrosion propagation can also be delayed.

In a specific embodiment, the hollow portions 145 are set in the first metal ring portion 142 or the second metal ring portion 143, as illustrated in FIG. 4 or FIG. 5. By setting the first metal ring portion 142 or the second metal ring portion 143 as a mesh structure, the interface between the two layers at the position where the metal film layer 140 is set becomes more complex, providing a longer path for water and oxygen intrusion, thereby delaying water and oxygen corrosion.

FIG. 7 is a schematic diagram of a second type of display panel according to a second embodiment of the present application. Referring to FIG. 7, the present embodiment provides an alternative solution for blocking metal corrosion. In particular, the metal film layer 140 is oxidized to achieve the effect of blocking the spread of metal corrosion.

In particular, the metal film layer 140 further includes an annular oxide portion 144, a first metal ring portion 142, and a second metal ring portion 143. The first metal ring portion 142 is arranged to surround the display area 101. The annular oxide portion 144 is arranged to surround the first metal ring portion 142. The second metal ring portion 143 is arranged to surround the annular oxide portion 144. The annular oxide portion 144 is formed by oxidizing the metal film layer 140 to create an oxidized metal material.

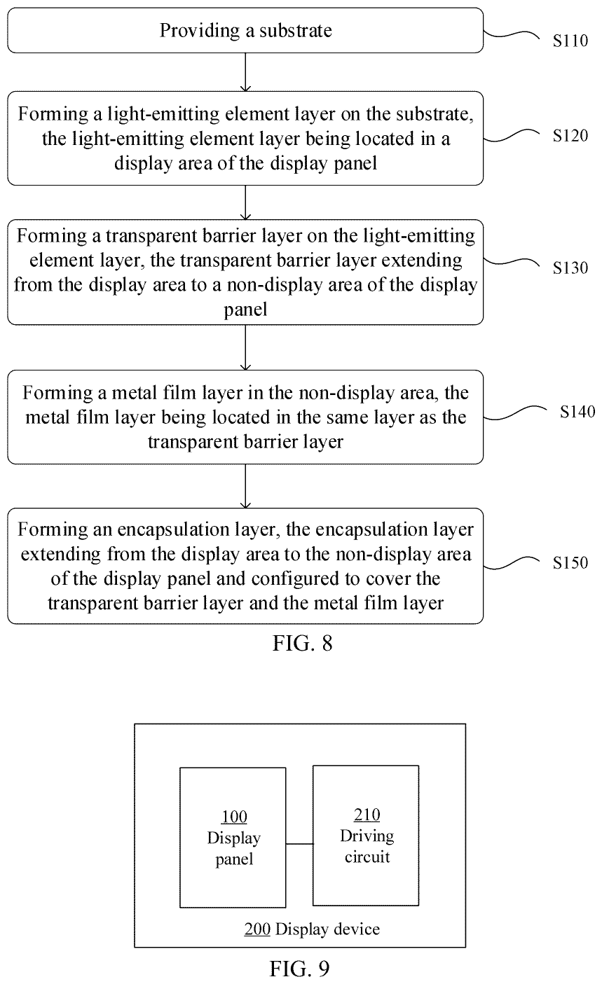

FIG. 8 is a flowchart of a method for manufacturing a display panel according to the present application. With reference to FIG. 8, and also referring to the previous FIGS. 1 to 7, the present application further discloses a method for manufacturing a display panel, corresponding to the above-mentioned display panels, the method includes the following operations:
S110: providing a substrate;
S120: forming a light-emitting element layer on the substrate, where the light-emitting element layer is disposed in the display area;
S130: forming a transparent barrier layer on the light-emitting element layer, with the transparent barrier layer extending from the display area to the non-display area;
S140: forming a metal film layer in the non-display area, with the metal film layer located in the same layer as the transparent barrier layer; and
S150: forming an encapsulation layer, with the encapsulation layer extending from the display area to the non-display area and covering the transparent barrier layer and the metal film layer.

This application sets a metal film layer 140 beneath the encapsulation layer 150 in the non-display area 102. By utilizing the capability of absorbing water and oxygen of the metal film layer 140 to a certain extent, when issues like edge encapsulation failure or aging of the display panel 100 over long-term use lead to water and oxygen intrusion into the metal film layer 140, the metal film layer 140 absorbs water and oxygen by sacrificing itself. That is, by oxidizing and corroding the metal film layer 140, it absorbs water and oxygen to prevent further intrusion of water and oxygen into the display area 101. Furthermore, this application prevents the formation of the metal film layer 140 from affecting the light-emitting elements 121 in the display area 101 during the manufacturing process by setting the transparent barrier layer 130. In this way, without affecting the display panel 100, the resistance of the display panel 100 to moisture and oxygen is improved. This enhances the encapsulation reliability of the display panel 100 and extends the service life of the display panel 100.

It is worth mentioning that the statement that the transparent barrier layer 130 and the metal film layer 140 are disposed in the same layer means that after the patterning process of the transparent barrier layer 130, the metal film layer 140 is formed in areas without the transparent barrier layer 130. This makes the metal film layer 140 and the transparent barrier layer 130 located in the same layer.

The transparent barrier layer is formed using a cathode pattern material, and the metal film layer is formed using a magnesium metal or silver metal material. The operation S140 includes:
S141: depositing a magnesium metal or silver metal material over the entire surface; and
S142: suppressing the adhesion of the magnesium metal or silver metal material within the display area by the cathode pattern material, so that the metal film layer is formed only in the non-display area.

In this embodiment, the metal film layer 140 is formed using magnesium metal or silver metal material. By the suppression effect of the transparent barrier layer 130, the deposition of magnesium metal or silver metal on the transparent barrier layer 130 can be prevented. In particular, after the transparent barrier layer 130 is formed, the magnesium metal or silver metal material is deposited over the entire surface. In the display area 101, the cathode pattern material suppresses the adhesion of the magnesium metal or silver metal material, so that the metal film layer 140 is only formed in the non-display area 102. The metal film layer 140 can be patterned by controlling the region of the transparent barrier layer 130, and no subsequent etching is required to remove excess metal film layer 140. In contrast, the light-emitting elements 121 within the display area 101 can be protected from the effects of subsequent processes. With the function of the transparent barrier layer 130, the metal film layer 140 can be deposited over the entire surface of the display panel 100 before forming the encapsulation layer 150. Since the metal film layer 140 cannot adhere to the transparent barrier layer 130 within the display area 101, it is ultimately formed only in the regions of the non-display area 102 that do not have the transparent barrier layer 130. Furthermore, the subsequent transparent barrier layer 130 does not affect the normal formation of the encapsulation layer 150.

FIG. 9 is a schematic diagram of a display device according to the present application. Referring to FIG. 9, the present application further discloses a display device. The display device 200 includes a driving circuit 210 and the display panel 100 as described in any of the above embodiments. The driving circuit 210 is configured to drive the display panel 100 for display.

It should be noted that the inventive concept of the present application can be formed into many embodiments, but the length of the application document is limited and so these embodiments cannot be enumerated one by one. Therefore, should no conflict be present, the various embodiments or technical features described above can be arbitrarily combined to form new embodiments. After the various embodiments or technical features are combined, the original technical effects may be enhanced.

The foregoing is a further detailed description of the present application with reference to some specific optional implementations, but it cannot be determined that the specific implementation of the present application is limited to these implementations. For those having ordinary skill in the technical field to which the present application pertains, several deductions or substitutions may be made without departing from the concept of the present application, and all these deductions or substitutions should be regarded as falling in the scope of protection of the present application.

What is claimed is:

1. A display panel, comprising a display area and a non-display area, wherein the display panel further comprises:
a substrate;
a light-emitting element layer, disposed on the substrate and located in the display area;
a transparent barrier layer, disposed on the light-emitting element layer and extending from the display area to the non-display area;
a metal film layer, disposed in the non-display area and located in the same layer as the transparent barrier layer; and
an encapsulation layer, extending from the display area to the non-display area, and disposed on the transparent barrier layer and the metal film layer.

2. The display panel as recited in claim 1, wherein the transparent barrier layer is formed using a cathode pattern material, and wherein the metal film layer is formed using a magnesium metal or silver metal material;
wherein after the transparent barrier layer is formed, the magnesium metal or silver metal material is deposited over an entire surface to form the metal film layer;
wherein in the display area, the cathode pattern material is configured to suppress an adhesion of the magnesium metal or silver metal material, so that the metal film layer is formed only in the non-display area.

3. The display panel as recited in claim 1, wherein the encapsulation layer comprises a first inorganic layer, an organic encapsulation layer, and a second inorganic layer; wherein the first inorganic layer is disposed on the transparent barrier layer and the metal film layer; wherein the organic encapsulation layer is disposed on the first inorganic layer, and wherein the second inorganic layer is disposed on the organic encapsulation layer;
wherein the display panel further comprises an encapsulation barrier layer that is disposed in the non-display area and that is configured to block the organic encapsulation layer;
wherein the first inorganic layer and the second inorganic layer extend from the encapsulation barrier layer in a direction of getting farther away from the display area, and wherein on the encapsulation barrier layer, the first inorganic layer and the second inorganic layer are in direct contact with each other.

4. The display panel as recited in claim 3, further comprising at least two blocking structures, the at least two blocking structures being disposed on a side of the encapsulation barrier layer facing towards the display area and located below the first inorganic layer;
wherein there is defined a gap between the at least two blocking structures, and wherein the metal film layer is disposed to cover the at least two blocking structures and the gap.

5. The display panel as recited in claim 1, wherein the metal film layer comprises at least one annular notch, the at least one annular notch dividing the metal film layer into a first metal ring portion and a second metal ring portion, the at least one annular notch surrounding the non-display area.

6. The display panel as recited in claim 1, wherein the metal film layer further comprises an annular oxide portion, a first metal ring portion, and a second metal ring portion; wherein the first metal ring portion is disposed to surround the display area, wherein the annular oxide portion is disposed to surround the first metal ring portion, wherein the second metal ring portion is disposed to surround the annular oxide portion;
wherein the annular oxide portion is formed by oxidizing the metal film layer to create the annular oxide portion of an oxidized metal material.

7. The display panel as recited in claim 1, wherein the metal film layer comprises a plurality of hollow portions, which are arranged in an array;
wherein the metal film layer is of a mesh structure.

8. The display panel as recited in claim 1, wherein the light-emitting element layer comprises a plurality of light-emitting elements that are arranged in an array; wherein each of the plurality of light-emitting elements comprises an anode, an organic light-emitting layer, and a cathode; wherein the organic light-emitting layer is disposed between the anode and the cathode.

9. The display panel as recited in claim 3, wherein a side of the metal film layer facing away from the display area is covered by the first inorganic layer.

10. The display panel as recited in claim 5, wherein an extension of the transparent barrier layer is disposed at a location of the annular notch.

11. A method for manufacturing a display panel, comprising:
providing a substrate;
forming a light-emitting element layer on the substrate, the light-emitting element layer being located in a display area of the display panel;
forming a transparent barrier layer on the light-emitting element layer, the transparent barrier layer extending from the display area to a non-display area of the display panel;
forming a metal film layer in the non-display area, the metal film layer being located in the same layer as the transparent barrier layer; and
forming an encapsulation layer, the encapsulation layer extending from the display area to the non-display area of the display panel and configured to cover the transparent barrier layer and the metal film layer.

12. The method as recited in claim 11, wherein the transparent barrier layer is formed using a cathode pattern material, and wherein the metal film layer is formed using a magnesium metal or silver metal material; wherein the operation of forming the metal film layer in the non-display area, the metal film layer being located in the same layer as the transparent barrier layer comprises:
depositing the magnesium metal or silver metal material over an entire surface; and
in the display area, the cathode pattern material inhibiting an adhesion of the magnesium metal or silver metal material, so that the metal film layer is formed only in the non-display area.

13. A display device, comprising a driving circuit and a display panel, wherein the driving circuit is configured to drive the display panel for display;
wherein the display panel comprises a display area and a non-display area, wherein the display panel further comprises:
a substrate;
a light-emitting element layer, disposed on the substrate and located in the display area;
a transparent barrier layer, disposed on the light-emitting element layer and extending from the display area to the non-display area;
a metal film layer, disposed in the non-display area and located in the same layer as the transparent barrier layer; and
an encapsulation layer, extending from the display area to the non-display area, and disposed on the transparent barrier layer and the metal film layer.

14. The display device as recited in claim 13, wherein the transparent barrier layer is formed using a cathode pattern material, and wherein the metal film layer is formed using a magnesium metal or silver metal material;
wherein after the transparent barrier layer is formed, the magnesium metal or silver metal material is deposited over an entire surface to form the metal film layer;
wherein in the display area, the cathode pattern material is configured to suppress an adhesion of the magnesium metal or silver metal material, so that the metal film layer is formed only in the non-display area.

15. The display device as recited in claim 13, wherein the encapsulation layer comprises a first inorganic layer, an organic encapsulation layer, and a second inorganic layer; wherein the first inorganic layer is disposed on the transparent barrier layer and the metal film layer; wherein the organic encapsulation layer is disposed on the first inorganic layer, and wherein the second inorganic layer is disposed on the organic encapsulation layer;
wherein the display panel further comprises an encapsulation barrier layer that is disposed in the non-display area and that is configured to block the organic encapsulation layer;
wherein the first inorganic layer and the second inorganic layer extend from the encapsulation barrier layer in a direction of getting farther away from the display area, and wherein on the encapsulation barrier layer, the first inorganic layer and the second inorganic layer are in direct contact with each other.

16. The display device as recited in claim 15, wherein the display panel further comprises at least two blocking structures, the at least two blocking structures being disposed on a side of the encapsulation barrier layer facing towards the display area and located below the first inorganic layer;
wherein there is defined a gap between the at least two blocking structures, and wherein the metal film layer is disposed to cover the at least two blocking structures and the gap.

17. The display device as recited in claim 13, wherein the metal film layer comprises at least one annular notch, the at least one annular notch dividing the metal film layer into a first metal ring portion and a second metal ring portion, the at least one annular notch surrounding the non-display area.

18. The display device as recited in claim 13, wherein the metal film layer further comprises an annular oxide portion, a first metal ring portion, and a second metal ring portion; wherein the first metal ring portion is disposed to surround the display area, wherein the annular oxide portion is disposed to surround the first metal ring portion, wherein the second metal ring portion is disposed to surround the annular oxide portion;
wherein the annular oxide portion is formed by oxidizing the metal film layer to create the annular oxide portion of an oxidized metal material.

19. The display device as recited in claim 13, wherein the metal film layer comprises a plurality of hollow portions, which are arranged in an array;
wherein the metal film layer is of a mesh structure.

20. The display device as recited in claim 13, wherein the light-emitting element layer comprises a plurality of light-emitting elements that are arranged in an array; wherein each of the plurality of light-emitting elements comprises an anode, an organic light-emitting layer, and a cathode; wherein the organic light-emitting layer is disposed between the anode and the cathode.
